(19) United States
(12) Patent Application Publication
(10) Pub. No.: US 2022/0119949 A1
(43) Pub. Date: Apr. 21, 2022

(54) SUBSTRATE PROCESSING APPARATUS, RECORDING MEDIUM, AND METHOD OF PROCESSING SUBSTRATE

(71) Applicant: KOKUSAI ELECTRIC CORPORATION, Tokyo (JP)

(72) Inventors: Yoshimasa NAGATOMI, Toyama-shi (JP); Mika URUSHIHARA, Toyama-shi (JP); Takafumi SASAKI, Toyama-shi (JP)

(73) Assignee: KOKUSAI ELECTRIC CORPORATION, Tokyo (JP)

(21) Appl. No.: 17/563,566

(22) Filed: Dec. 28, 2021

Related U.S. Application Data
(63) Continuation of application No. PCT/JP2020/025776, filed on Jul. 1, 2020.

(30) Foreign Application Priority Data
Jul. 26, 2019 (JP) 2019-137583

(51) Int. Cl. C23C 16/455

(52) U.S. Cl. CPC C23C 16/45565; C23C 16/45519

(57) ABSTRACT

According to some embodiments of the present disclosure, there is provided a technique that includes: a process gas nozzle configured to supply a process gas into a process chamber; two or more inert gas nozzles installed at each of both sides of the process gas nozzle in a circumferential direction of the process chamber and configured to supply an inert gas into the process chamber; a process gas supplier configured to supply the process gas to the process gas nozzle; an inert gas supplier configured to supply the inert gas to each of the inert gas nozzles; and a controller configured to be capable of controlling a flow rate of the process gas supplied from the process gas supplier to the process gas nozzle and a flow rate of the inert gas supplied from the inert gas supplier to each of the inert gas nozzles, respectively.

### CROSS-REFERENCE TO RELATED APPLICATION

This application is a Bypass Continuation Application of PCT International Application No. PCT/JP2020/025776, filed on Jul. 1, 2020, the international application being based upon and claiming the benefit of priority from Japanese Patent Application No. 2019-137583, filed on Jul. 26, 2019, the entire contents of which are incorporated herein by reference.

### TECHNICAL FIELD

The present disclosure relates to a substrate processing apparatus, a recording medium, and a method of processing a substrate.

### BACKGROUND

In the related art, a substrate processing apparatus configured to form a film on the surface of a substrate (wafer) arranged in a process chamber is known.

### SUMMARY

Some embodiments of the present disclosure provide a technique capable of controlling the film thickness distribution of a film formed on a substrate.

According to some embodiments of the present disclosure, there is provided a technique that includes: a process gas nozzle configured to supply a process gas into a process chamber; two or more inert gas nozzles installed at each of both sides of the process gas nozzle in a circumferential direction of the process chamber and configured to supply an inert gas into the process chamber; a process gas supplier configured to supply the process gas to the process gas nozzle; an inert gas supplier configured to supply the inert gas to each of the inert gas nozzles; and a controller configured to be capable of controlling a flow rate of the process gas supplied from the process gas supplier to the process gas nozzle and a flow rate of the inert gas supplied from the inert gas supplier to each of the inert gas nozzles, respectively.

### BRIEF DESCRIPTION OF DRAWINGS

The accompanying drawings, which are incorporated in and constitute a part of the specification, illustrate some embodiments of the present disclosure.

FIG. 1 is a schematic configuration view of a vertical process furnace of a substrate processing apparatus according to some embodiments of the present disclosure, in which a portion of the process furnace is shown in a longitudinal section.

FIG. 2 is a schematic configuration view of a vertical process furnace of a substrate processing apparatus according to some embodiments of the present disclosure, in which a portion of the process furnace is shown in a cross section.

FIG. 3 is a view showing a periphery of a gas supply system of a substrate processing apparatus according to some embodiments of the present disclosure in a longitudinal section.

FIG. 4 is a diagram explaining gas supply of a substrate processing apparatus according to some embodiments of the present disclosure.

FIG. 5 is a block diagram showing a control system of a controller of a substrate processing apparatus according to some embodiments of the present disclosure.

FIG. 6 is a diagram showing a film-forming sequence of a substrate processing apparatus according to some embodiments of the present disclosure.

FIG. 7 is a diagram showing a modification of a film-forming sequence of a substrate processing apparatus according to some embodiments of the present disclosure.

FIG. 8 is a schematic configuration view of a vertical process furnace of a substrate processing apparatus according to modifications, in which a portion of the process furnace is shown in a cross section.

FIG. 9 is a view showing a periphery of a gas supply system of a substrate processing apparatus according to modifications in a longitudinal section.

FIG. 10 is a view showing a periphery of a gas supply system of a substrate processing apparatus according to modifications in a longitudinal section.

FIG. 11A is a diagram showing a gas flow in a process chamber in a first processing step of the film-forming sequence of FIG. 6. FIG. 11B is a diagram showing a film thickness distribution of a film formed on a substrate by the film-forming sequence of FIG. 6.

FIG. 12A is a diagram showing a gas flow in a process chamber in a first processing step of the film-forming sequence of FIG. 7. FIG. 12B is a diagram showing a film thickness distribution of a film formed on a substrate by the film-forming sequence of FIG. 7.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components are described in detail so as not to obscure aspects of the various embodiments.

### EMBODIMENTS

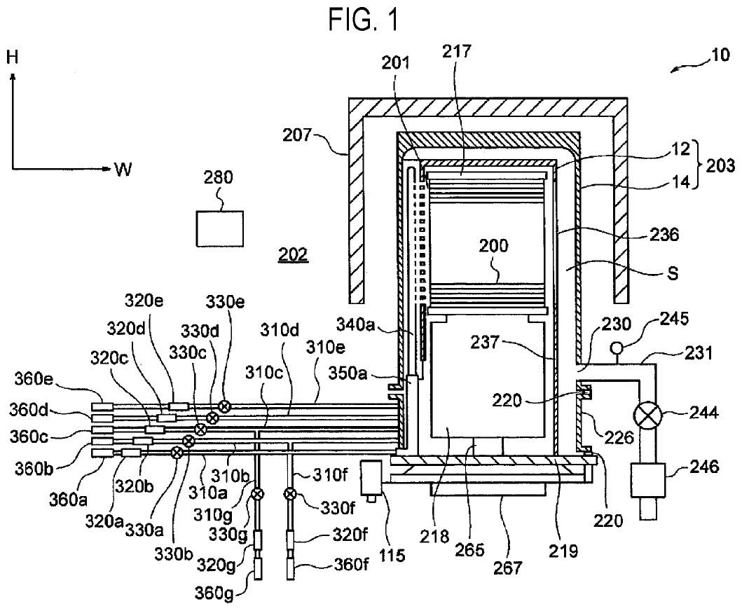

An example of a substrate processing apparatus according to some embodiments of the present disclosure will be described with reference to FIGS. 1 to 7. In the drawings, an arrow H indicates an apparatus perpendicular direction (vertical direction), an arrow W indicates an apparatus width direction (horizontal direction), and an arrow D indicates an apparatus depth direction (horizontal direction).

### (Overall Configuration of Substrate Processing Apparatus 10)

As shown in FIG. 1, a substrate processing apparatus 10 includes a controller 280 configured to control respective components, and a process furnace 202, and the process furnace 202 includes a heater 207 which is a heating means or unit. The heater 207 is formed in a cylindrical shape and is supported by a heater base (not shown) to be installed in the apparatus perpendicular direction. The heater 207 also functions as an activation mechanism configured to activate a process gas with heat. Details of the controller 280 will be described later.

A reaction tube 203 constituting a reaction container is disposed upright inside the heater 207 to be concentric with the heater 207. The reaction tube 203 is made of, for example, a heat resistant material such as quartz (SiO₂) or silicon carbide (SiC). The substrate processing apparatus 10 is of a so-called hot-wall type.

The reaction tube 203 includes a cylindrical inner tube 12 and a cylindrical outer tube 14 installed to surround the inner tube 12. The inner tube 12 is disposed to be concentric with the outer tube 14, and a space S is formed between the inner tube 12 and the outer tube 14. The inner tube 12 is an example of a tube member.

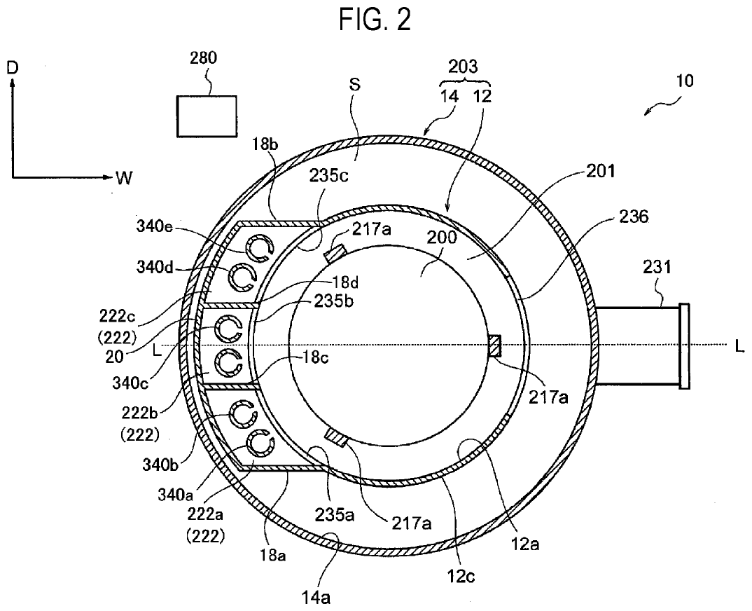

The inner tube 12 is formed with its lower end opened and with its upper end including a ceiling closed with a flat wall body. Further, the outer tube 14 is also formed with its lower end opened and with its upper end including a ceiling closed with a flat wall body. Further, as shown in FIG. 2, a plurality of nozzle chambers 222 (three nozzle chambers 222 in the embodiments) are formed in the space S formed between the inner tube 12 and the outer tube 14. Details of the nozzle chambers 222 will be described later.

A process chamber 201 in which wafers 200 as substrates are processed is formed inside the inner tube 12. Further, the process chamber 201 may accommodate a boat 217, which is an example of a substrate holder capable of holding the wafers 200 in such a state that the wafers 200 are aligned in a horizontal posture and in multiple stages along a vertical direction, and the inner tube 12 surrounds the accommodated wafers 200. Details of the inner tube 12 will be described later.

The lower end of the reaction tube 203 is supported by a cylindrical manifold 226. The manifold 226 is made of, for example, metal such as nickel alloy or stainless steel, or is made of a heat resistant material such as quartz or SiC. A flange is formed at the upper end portion of the manifold 226, and the lower end portion of the outer tube 14 is installed on the flange. An airtight member 220 such as an O-ring is disposed between the flange and the lower end portion of the outer tube 14 to keep an interior of the reaction tube 203 airtight.

A seal cap 219 is airtightly installed at an opening at the lower end of the manifold 226 via the airtight member 220 such as the O-ring, such that the opening side of the lower end of the reaction tube 203, that is, the opening of the manifold 226 is airtightly blocked. The seal cap 219 is made of, for example, metal such as nickel alloy or stainless steel, and is formed in a disc shape. The seal cap 219 may be configured to with its outside being covered with a heat resistant material such as quartz or SiC.

A boat support 218 configured to support the boat 217 is installed on the seal cap 219. The boat support 218 is made of, for example, a heat resistant material such as quartz or SiC, and functions as a heat insulator.

The boat 217 is installed uprightly on the boat support 218. The boat 217 is made of, for example, a heat resistant material such as quartz or SiC. The boat 217 includes a bottom plate (not shown) fixed to the boat support 218, and a ceiling plate arranged above the bottom plate, and a plurality of posts 217a (see FIG. 2) are provided between the bottom plate and the ceiling plate.

The boat 217 holds a plurality of wafers 200 to be processed in the process chamber 201 in the inner tube 12. The plurality of wafers 200 are supported by the posts 217a of the boat 217 in such a state that the wafers 200 are held in a horizontal posture at regular intervals from one another with centers of the wafers 220 aligned with one another, and a mounting direction of the wafers 200 is an axial direction of the reaction tube 203. That is, the centers of the wafers 200 are aligned with a central axis of the boat 217, and the central axis of the boat 217 coincides with a central axis of the reaction tube 203.

A rotation mechanism 267 configured to rotate the boat is installed under the seal cap 219. A rotary shaft 265 of the rotation mechanism 267 is connected to the boat support 218 through the seal cap 219, and the rotation mechanism 267 rotates the boat 217 via the boat support 218 to rotate the wafers 200.

The seal cap 219 is vertically moved up or down by an elevator 115 as an elevating mechanism installed outside the reaction tube 203, such that the boat 217 may be loaded/unloaded into/out of the process chamber 201.

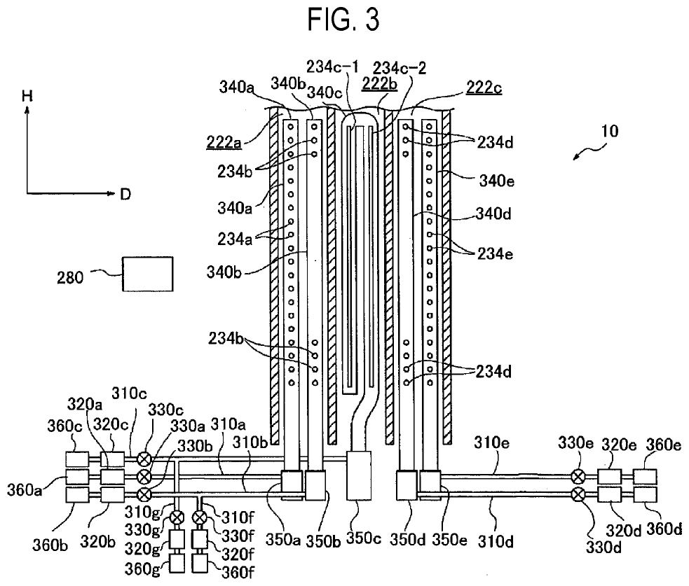

Nozzle supports 350a to 350e (see FIG. 3) that support gas nozzles 340a to 340e configured to supply a gas into the interior of the process chamber 201 are installed at the manifold 226 to penetrate the manifold 226 (the gas nozzle 340a and the nozzle support 350a are shown in FIG. 1). The nozzle supports 350a to 350e are made of, for example, a material such as a nickel alloy or stainless steel.

Gas supply pipes 310a to 310e configured to supply a gas into the interior of the process chamber 201 are connected to some ends of the nozzle supports 350a to 350e, respectively. Further, the gas nozzles 340a to 340e are connected to the other ends of the nozzle supports 350a to 350e, respectively. The gas nozzles 340a to 340e are made of, for example, a heat resistant material such as quartz or SiC. Details of the gas nozzles 340a to 340e and the gas supply pipes 310a to 310e will be described later.

On the other hand, an exhaust port 230 is formed at the outer tube 14 of the reaction tube 203. The exhaust port 230 is formed below a second exhaust port 237, which will be described later, and an exhaust pipe 231 is connected to the exhaust port 230.

A vacuum pump 246 as a vacuum exhauster is connected to the exhaust pipe 231 via a pressure sensor 245 configured to detect an internal pressure of the process chamber 201, and an auto pressure controller (APC) valve 244 as a pressure regulator. The exhaust pipe 231 on the downstream side of the vacuum pump 246 is connected to a waste gas treatment mechanism (not shown) or the like. As a result, by controlling an output of the vacuum pump 246 and an opening state of the APC valve 244, the interior of the process chamber 210 may be vacuum-exhausted such that the internal pressure of the process chamber 210 reaches a predetermined pressure (vacuum degree).

A temperature sensor (not shown) serving as a temperature detector is installed inside the reaction tube 203, and based on temperature information detected by the temperature sensor, an electric power supplied to be the heater 207 is regulated such that a temperature distribution of the interior of the process chamber 201 becomes a desired temperature distribution.

In this configuration, in the process furnace 202, the boat 217 where a plurality of wafers 200 to be batch-processed are mounted in multiple stages is loaded into the process chamber 201 by the boat support 218. Then, the wafers 200 loaded into the process chamber 201 is heated to a predetermined temperature by the heater 207. An apparatus including such a process furnace is called a vertical batch apparatus.

### (Configuration of Main Components)

Next, the inner tube 12, the nozzle chamber 222, the gas supply pipes 310a to 310e, the gas nozzles 340a to 340e, and the controller 280 will be described.

### [Inner Tube 12]

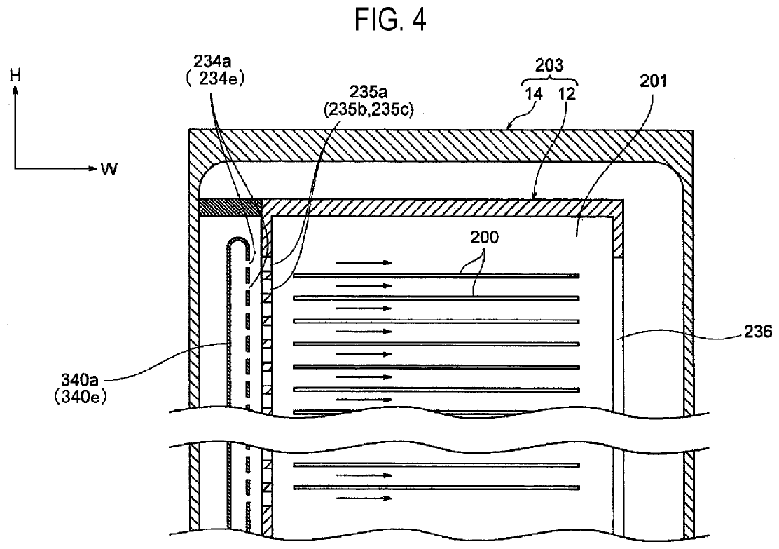

As shown in FIGS. 2 and 4, supply slits 235a, 235b, and 235c, which are examples of supply holes, and a first exhaust port 236, which is an example of a discharger, facing the supply slits 235a, 235b, and 235c, are formed at a peripheral wall of the inner tube 12. Further, as shown in FIG. 1, a second exhaust port 237, which is an example of a discharger of an opening area smaller than that of the first exhaust port 236, is formed below the first exhaust port 236 at the peripheral wall of the inner tube 12. In this way, the supply slits 235a, 235b, and 235c, the first exhaust port 236, and the second exhaust port 237 are formed at different positions in the circumferential direction of the inner tube 12.

As shown in FIG. 1, the first exhaust port 236 formed at the inner tube 12 is formed at a region from the lower end side to the upper end side of the process chamber 201 in which the wafers 200 are accommodated (hereinafter, may be referred to as a “wafer region”). The first exhaust port 236 is formed to allow the process chamber 201 to be in fluid communication with the space S, and the second exhaust port 237 is formed to exhaust an atmosphere below the process chamber 201.

That is, the first exhaust port 236 is a gas exhaust port configured to exhaust the internal atmosphere of the process chamber 201 to the space S, and a gas exhausted via the first exhaust port 236 is exhausted via the exhaust pipe 231 to the outside of the reaction pipe 203 via the space S and the exhaust port 230. Similarly, a gas exhausted via the second exhaust port 237 is exhausted via the exhaust pipe 231 to the outside of the reaction pipe 203 via the lower side of the space S and the exhaust port 230.

In this configuration, a gas which passed through the wafers 200 is exhausted via the outside of the tube, such that a difference between a pressure of an exhauster such as the vacuum pump 246 and a pressure in the wafer region may be reduced to minimize a pressure loss. Then, by minimizing the pressure loss, the pressure in the wafer region may be lowered, and therefore, a flow velocity in the wafer region may be increased and a loading effect may be mitigated.

On the other hand, a plurality of supply slits 235a formed at the peripheral wall of the inner tube 12 are formed in a horizontally-long slit shape in the vertical direction, and allow a first nozzle chamber 222a to be in fluid communication with the process chamber 201.

Further, a plurality of supply slits 235b are formed in a horizontally-long slit shape in the vertical direction, and are arranged at a lateral side of the supply slits 235a. Further, the supply slits 235b allows a second nozzle chamber 222b to be in fluid communication with the process chamber 201.

Further, a plurality of supply slits 235c are formed in a horizontally long slit shape in the vertical direction, and are arranged at the opposite side of the supply slits 235a with the supply slits 235b interposed therebetween. Further, the supply slits 235c allows a third nozzle chamber 222c to be in fluid communication with the process chamber 201.

A gas supply efficiency may be improved by setting a length of each of the supply slits 235a to 235c to be equal to a length of each of the nozzle chambers 222a to 222c in the circumferential direction of the inner tube 12.

Further, each of the supply slits 235a to 235c is smoothly formed such that edges as four corners draw curved surfaces. By performing R-chamfering or the like on each edge to form the edge in a shape of a curved surface, it is possible to suppress stagnation of a gas on the periphery of the edge, such that a film may be prevented from being formed on the edge and a film that is formed on the edge may be prevented from being peeled off from the edge.

Further, an opening (not shown) formed such that the gas nozzles 340a to 340e are installed at the nozzle chambers 222a to 222c of the nozzle chamber 222 in a corresponding manner is formed at a lower end of an inner peripheral surface 12a of the inner tube 12 at the side of the supply slits 235a to 235c.

As shown in FIG. 4, the supply slits 235a to 235c are formed to be respectively arranged between the wafers 200 adjacent to each other of the plurality of wafers 200 mounted, in the vertical direction, on the boat 217 accommodated in the process chamber 201 (see FIG. 1).

The supply slits 235a to 235c may be formed to be located between the wafers 200, between the bottom plate of the boat 217 and the wafer 200, and between the ceiling plate of the boat 17 and the wafer 200, from a location between the bottom plate of the boat 217 and the lowermost wafer 200, which may be mounted on the boat 217, to a location between the ceiling plate of the boat 217 and the uppermost wafer 200, which may be mounted on the boat 217.

Further, as shown in FIG. 1, the first exhaust port 236 is formed in the wafer region of the inner tube 12, and allows the process chamber 201 to be in fluid communication with the space S. The second exhaust port 237 is formed from a position higher than an upper end of the exhaust port 230 to a position higher than a lower end of the exhaust port 230.

### [Nozzle Chamber 222]

As shown in FIG. 2, the nozzle chambers 222 are formed in the space S between the outer peripheral surface 12c of the inner tube 12 and the inner peripheral surface 14a of the outer tube 14. The nozzle chambers 222 include the first nozzle chamber 222a extending in the vertical direction, the second nozzle chamber 222b extending in the vertical direction, and the third nozzle chamber 222c extending in the vertical direction. Further, the first nozzle chamber 222a, the second nozzle chamber 222b, and the third nozzle chamber 222c are formed in this order in the circumferential direction of the process chamber 201.

Specifically, the nozzle chambers 222 are formed between a first partition 18a extending to protrude from the outer peripheral surface 12c of the inner tube 12 toward the outer tube 14 and a second partition 18b extending to protrude from the outer peripheral surface 12c of the inner tube 12 toward the outer tube 14 and between an arc-like ceiling plate 20, which connects a leading end of the first partition 18a and a leading end of the second partition 18b, and the inner tube 12.

Further, a third partition 18c and a fourth partition 18d extending from the outer peripheral surface 12c of the inner tube 12 toward the ceiling plate 20 side are formed inside the nozzle chambers 222, and the third partition 18c and the fourth partition 18d are arranged from the first partition 18a to the second partition 18b side in this order. Further, the ceiling plate 20 is separated from the outer tube 14. Further, a leading end of the third partition 18c and a leading end of the fourth partition 18d reach the ceiling plate 20. The partitions 18a to 18d and the ceiling plate 20 are examples of partition members.

Further, the partitions 18a to 18d and the ceiling plate 20 are formed from the ceiling portion of the nozzle chambers 222 to the lower end portion of the reaction tube 203.

As shown in FIG. 2, the first nozzle chamber 222a is formed to be surrounded by the inner tube 12, the first partition 18a, the third partition 18c, and the ceiling plate 20, and the second nozzle chamber 222b is formed to be surrounded by the inner tube 12, the third partition 18c, the fourth partition 18d, and the ceiling plate 20. Further, the third nozzle chamber 222c is formed to be surrounded by the inner tube 12, the fourth partition 18d, the second partition 18b, and the ceiling plate 20. As a result, each of the nozzle chambers 222a to 222c is formed in a shape with its lower end opened and with its upper end including a ceiling closed with a wall body constituting the ceiling surface of the inner tube 12, and extends in the vertical direction.

Then, as described above, the supply slits 235a that allows the first nozzle chamber 222a to be in fluid communication with the process chamber 201 are arranged in the vertical direction and are formed on the peripheral wall of the inner tube 12. Further, the supply slits 235b that allows the second nozzle chamber 222b to be in fluid communication with the process chamber 201 are arranged in the vertical direction and are formed on the peripheral wall of the inner tube 12, and the supply slits 235c that allows the third nozzle chamber 222c to be in fluid communication with the process chamber 201 are arranged in the vertical direction and are formed on the peripheral wall of the inner tube 12.

Further, the third partition 18c and the fourth partition 18d may not be installed. In this case, the gas nozzles 340a to 340e are arranged in one nozzle chamber 222. However, in a case where no third partition 18c and fourth partition 18d are installed, a directivity of flow of a N₂ gas is lowered, and therefore, a controllability of a film thickness distribution is lowered, which may increase the flow rate of the N₂ gas. By installing the third partition 18c and the fourth partition 18d, the controllability of the film thickness distribution is improved, such that the flow rate of the N₂ gas may be reduced.

[Gas Nozzles 340a to 340e]

The gas nozzles 340a to 340e extend in the vertical direction, and are installed in the nozzle chambers 222a to 222c, respectively, as shown in FIGS. 2 and 3. Each of the gas nozzles 340b and 340c is used as a process gas nozzle configured to supply a precursor gas or a reaction gas as a process gas, into the process chamber 201. Further, each of the gas nozzles 340a to 340e is used as an inert gas nozzle configured to supply an inert gas into the process chamber 201. Further, the gas nozzle 340a which is in fluid communication with the gas supply pipe 310a and the gas nozzle 340b which is in fluid communication with the gas supply pipe 310b are arranged in the first nozzle chamber 222a. Further, the gas nozzle 340c which is in fluid communication with the gas supply pipe 310c is arranged in the second nozzle chamber 222b. Further, the gas nozzle 340d which is in fluid communication with the gas supply pipe 310d and the gas nozzle 340e which is in fluid communication with the gas supply pipe 310e are arranged in the third nozzle chamber 222c.

When viewed from above, the gas nozzle 340c is installed between the gas nozzles 340a and 340b and the gas nozzles 340d and 340e in the circumferential direction of the process chamber 201. In other words, two gas nozzles 340a and 340b and two gas nozzles 340e and 340d are respectively installed at both sides of the gas nozzle 340c in the circumferential direction. That is, two or more gas nozzles 340a and 340b and two or more gas nozzles 340e and 340d as inert gas nozzles are respectively installed on both sides of a straight line L passing through the gas nozzle 340c as the process gas nozzle and the first exhaust port 236 in a plane view. In the embodiments, the gas nozzles 340a and 340b and the gas nozzles 340e and 340d as the inert gas nozzles are respectively arranged in line symmetry with the straight line L as an axis of symmetry. Further, the gas nozzles 340a and 340b and the gas nozzles 340e and 340d as the inert gas nozzles may not be arranged in line symmetry. Further, the gas nozzles 340a and 340b and the gas nozzle 340c are partitioned by the third partition 18c, and the gas nozzle 340c and the gas nozzles 340d and 340e are partitioned by the fourth partition 18d. That is, the gas nozzle 340c, the gas nozzles 340a and 340b, and the gas nozzles 340d and 340e are arranged in the partitioned spaces, respectively. As a result, it is possible to prevent gases from being mixed among the respective nozzle chambers 222.

The gas nozzles 340a, 340b, 340d, and 340e are each configured as an I-type (I-shaped) long nozzle.

Injection holes 234a and 234e configured to inject a gas are formed on the peripheral surfaces of the gas nozzles 340a and 340e to face the supply slits 235a and 235c e, respectively. Specifically, the injection holes 234a and 234e of the gas nozzles 340a and 340e may be formed in a central portion of a vertical width of each of the supply slits 235a and 235c to correspond to each of the supply slits 235a and 235c. For example, when 25 supply slits 235a and 235c are formed, 25 injection holes 234a and 234e may be formed, respectively. That is, the supply slits 235a and 235c and the injection holes 234a and 234e may be formed by the number of wafers 200 to be mounted+1. In this way, a range in which the injection holes 234a and 234e are formed in the vertical direction covers a range in which the wafers 200 are arranged in the vertical direction.

Further, injection holes 234b and 234d configured to inject a gas are formed on the peripheral surfaces of the gas nozzles 340b and 340d to face the supply slits 235a and 235c, respectively. Specifically, the injection holes 234b and 234d of the gas nozzles 340b and 340d may be formed in a central portion of a vertical width of each of the supply slits 235a and 235c to correspond to each of the supply slits 235a and 235c. Further, a plurality of injection holes 234b and 234d are arranged in the vertical direction in the upper and lower portions of the gas nozzles 340b and 340d in the vertical direction. In this way, the injection holes 234b and 234d formed in the upper portion of the gas nozzles 340b and 340d cover, in the vertical direction, a range in which the uppermost wafer 200 is arranged. Further, the injection holes 234b and 234d formed in the lower portion of the gas nozzles 340b and 340d cover, in the vertical direction, a range in which the lowermost wafer 200 is arranged.

In the embodiments, the injection holes 234a, 234b, 234d, and 234e are pinhole-shaped. Further, an injection direction in which a gas is injected from the injection holes 234a, 234b, 234d, and 234e faces the center of the process chamber 201 when viewed from above, and as shown in FIG. 4, when viewed from side, it faces between adjacent wafers 200, a portion above an upper surface of the uppermost wafer 200, or a portion below a lower surface of the lowermost wafer 200. Further, the injection directions in which the gas is injected from the respective injection holes 234a, 234b, 234d, and 234e are set to be the same direction.

The gas nozzle 340c is configured as a U-typed (U-shaped) gas nozzle folded back at its upper end. Further, a pair of slit-shaped injection holes 234c-1 and 234c-2 extending in the vertical direction are formed at the gas nozzle 340c. Specifically, the injection holes 234c-1 and 234c-2 are formed in portions of the gas nozzle 340c extending in the vertical direction, respectively. Further, a range in which the injection holes 234c-1 and 234c-2 are formed in the vertical direction covers, in the vertical direction, the range in which the wafers 200 are arranged in the vertical direction. Further, the pair of injection holes 234c-1 and 234c-2 are formed to face the supply slit 235b respectively.

The gas injected from the injection holes 234a, 234b, 234c-1, 234c-2, 234d, and 234e of the respective gas nozzles 340a to 340e is supplied into the process chamber 201 via the supply slits 235a to 235c formed at the inner tube 12 forming a front wall of each of the nozzle chambers 222a to 222c. Then, the gas supplied into the process chamber 201 flows along the upper surface and the lower surface of each wafer 200 (see arrows in FIG. 4).

[Gas Supply Pipes 310a to 310e]

As shown in FIGS. 1 and 3, the gas supply pipe 310a is in fluid communication with the gas nozzle 340a via the nozzle support 350a, and the gas supply pipe 310b is in fluid communication with the gas nozzle 340b via the nozzle support 350b. Further, the gas supply pipe 310c is in fluid communication with the gas nozzle 340c via the nozzle support 350c, and the gas supply pipe 310d is in fluid communication with the gas nozzle 340d via the nozzle support 350d. Further, the gas supply pipe 310e communicates with the gas nozzle 340e via the nozzle support 350e.

At the gas supply pipe 310a, an inert gas supply source 360a that supplies an inert gas as a process gas, a mass flow controller (MFC) 320a, which is an example of a flow rate controller, and a valve 330a, which is an opening/closing valve, are installed sequentially from the upstream side in the gas flow direction. A first inert gas supplier includes the inert gas supply source 360a, the MFC 320a, and the valve 330a.

At the gas supply pipe 310b, a first precursor gas supply source 360b that supplies a first precursor gas (a reaction gas, also referred to as a reactant) as a process gas, a MFC 320b, and a valve 330b are installed sequentially from the upstream side in the gas flow direction. A first process gas supplier includes the first precursor gas supply source 360b, the MFC 320b, and the valve 330b .

At the gas supply pipe 310c, a second precursor gas supply source 360c that supplies a second precursor gas (a precursor gas, also referred to as a source gas) as a process gas, a MFC 320c, and a valve 330c are installed sequentially from the upstream side in the gas flow direction. A second process gas supplier includes the second precursor gas supply source 360c, the MFC 320c, and the valve 330c. Further, a process gas supply system includes the second process gas supplier.

At the gas supply pipe 310d, an inert gas supply source 360d that supplies an inert gas as a process gas, a MFC 320d, and a valve 330d are installed sequentially from the upstream side in the gas flow direction. A second inert gas supplier includes the inert gas supply source 360d, the MFC 320d, and the valve 330d.

At the gas supply pipe 310e, an inert gas supply source 360e that supplies an inert gas as a process gas, a MFC 320e, and a valve 330e are installed sequentially from the upstream side in the gas flow direction. A third inert gas supplier includes the inert gas supply source 360e, the MFC 320e, and the valve 330e.

A gas supply pipe 310f configured to supply an inert gas as a process gas is connected to the gas supply pipe 310b at the downstream side of the valve 330b in the gas flow direction. At the gas supply pipe 310f, an inert gas supply source 360f that supplies an inert gas as a process gas, a MFC 320f, and a valve 330f are installed sequentially from the upstream side in the gas flow direction. A fourth inert gas supplier includes the inert gas supply source 360f, the MFC 320f, and the valve 330f.

A gas supply pipe 310g configured to supply an inert gas as a process gas is connected to the gas supply pipe 310c at the downstream side of the valve 330c in the gas flow direction. At the gas supply pipe 310g, an inert gas supply source 360g that supplies an inert gas as a process gas, a MFC320g, and a valve 330g are installed sequentially from the upstream side in the gas flow direction. A fifth inert gas supplier includes the inert gas supply source 360g, the MFC 320g, and the valve 330g.

Further, the inert gas supply sources 360a, 360d, 360e, 360f, and 360g that supply the inert gases are connected to a common supply source. Further, an inert gas supply system includes the above-mentioned first to fourth inert gas suppliers. Further, a gas supply system includes the above-mentioned process gas supply system and inert gas supply system.

Further, an example of the first precursor gas supplied from the first precursor gas supply source 360b may include an ozone (O₃) gas or the like. Further, an example of the second precursor gas supplied from the second precursor gas supply source 360c may include a hafnium (Hf)-containing gas (hereinafter, simply referred to as a Hf gas) or the like. The precursor of the Hf gas is a gas containing at least a Hf element and an amino group (NR—). Here, R is hydrogen (H), an alkyl group, or the like. An example of such a precursor may include tetrakis(ethylmethylamide)hafnium (TEMAHf). The precursor of the Hf gas may be a material further containing a cyclopenta group (Cp). Further, an example of the inert gas supplied from each of the inert gas supply sources 360a, 360d, 360e, 360f, and 360g may include a nitrogen (N₂) gas or the like.

A circumferential length of the first nozzle chamber 222a, a circumferential length of the second nozzle chamber 222b, and a circumferential length of the third nozzle chamber 222c are the same in the circumferential direction of the process chamber 201. The first nozzle chamber 222a, the second nozzle chamber 222b, and the third nozzle chamber 222c are examples of a supply chamber.

### [Controller 280]

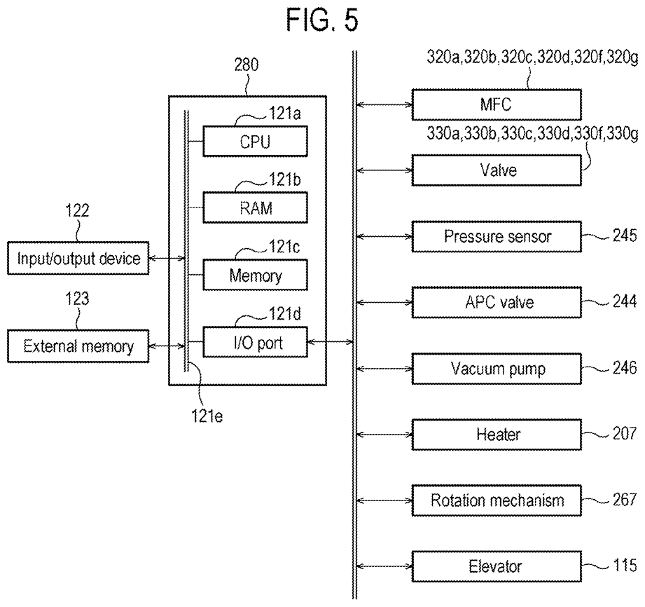

FIG. 5 is a block diagram showing a control configuration of the substrate processing apparatus 10. The controller 280 (a so-called controller) of the substrate processing apparatus 10 is configured as a computer. The computer includes a central processing unit (CPU) 121a, a random access memory (RAM) 121b, a memory 121c, and an I/O port 121d.

The RAM 121b, the memory 121c, and the I/O port 121d are configured to be capable of exchanging data with the CPU 121a via an internal bus 121e. An input/output device 122 including, e.g., a touch panel or the like, is connected to the controller 280.

The memory 121c includes, for example, a flash memory, a hard disk drive (HDD), or the like. A control program that controls operations of the substrate processing apparatus, a process recipe in which sequences and conditions of substrate processing to be described later are written, and the like are readably stored in the memory 121c.

The process recipe functions as a program that is combined to causes the controller 280 to execute each sequence in the substrate processing to be described later, to obtain a predetermined result. Hereinafter, the process recipe and the control program may be generally and simply referred to as a “program.”

When the term “program” is used herein, it may indicate a case of including the process recipe, a case of including the control program, or a case of including both the process recipe and the control program. The RAM 121b includes a memory area (work area) in which a program or data read by the CPU 121a is temporarily stored.

The I/O port 121d is connected to the MFCs 320a to 320g, the valves 330a to 330g, the pressure sensor 245, the APC valve 244, the vacuum pump 246, the heater 207, the temperature sensor, the rotation mechanism 267, the elevator 115, and so on.

The CPU 121a is configured to read and execute the control program from the memory 121c and is also configured to read the process recipe from the memory 121c according to an input of an operation command from the input/output device 122.

The CPU 121a is configured to control the flow rate regulating operation of various kinds of gases by the MFCs 320a to 320g, the opening/closing operation of the valves 330a to 330g, and the opening/closing operation of the APC valve 244, according to contents of the read recipe. Further, the CPU 121a is configured to control the pressure regulating operation performed by the APC valve 244 based on the pressure sensor 245, the actuating and stopping operation of the vacuum pump 246, and the temperature regulating operation performed by the heater 207 based on the temperature sensor. Further, the CPU 121a is configured to control the operation of rotating the boat 217 and adjusting the rotation speed of the boat 217 with the rotation mechanism 267, the operation of moving the boat 217 up or down by the elevator 115, and so on.

The controller 280 is not limited to a case where it is configured as a dedicated computer, but may be configured as a general-purpose computer. For example, the controller 280 in the embodiments may be configured by providing an external memory 123 that stores the above-mentioned program and installing the program on the general-purpose computer by using the external memory 123. Examples of the external memory may include a magnetic disc such as a hard disc, an optical disc such as a CD, a magneto-optical disc such as a MO, a semiconductor memory such as a USB memory, and the like.

### (Operation)

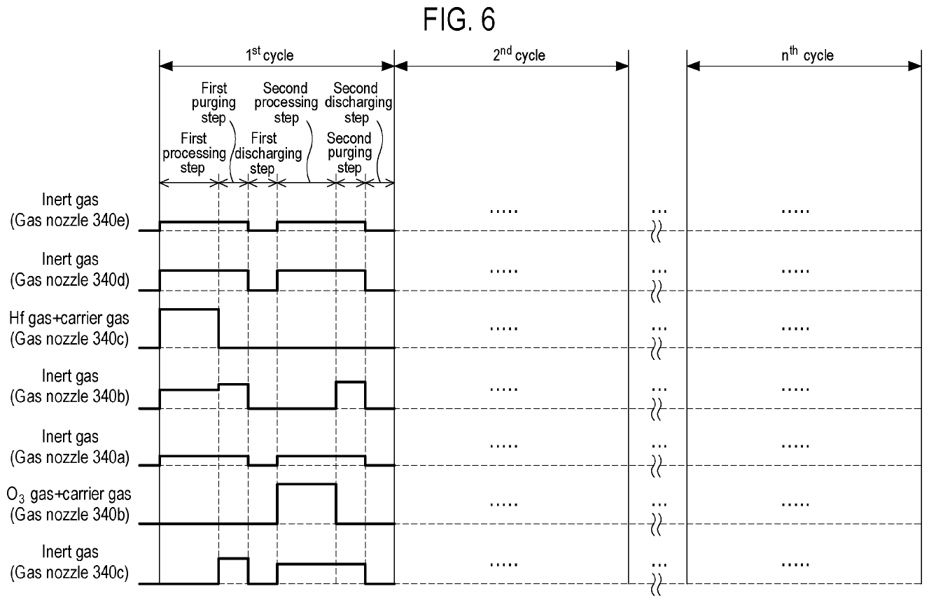

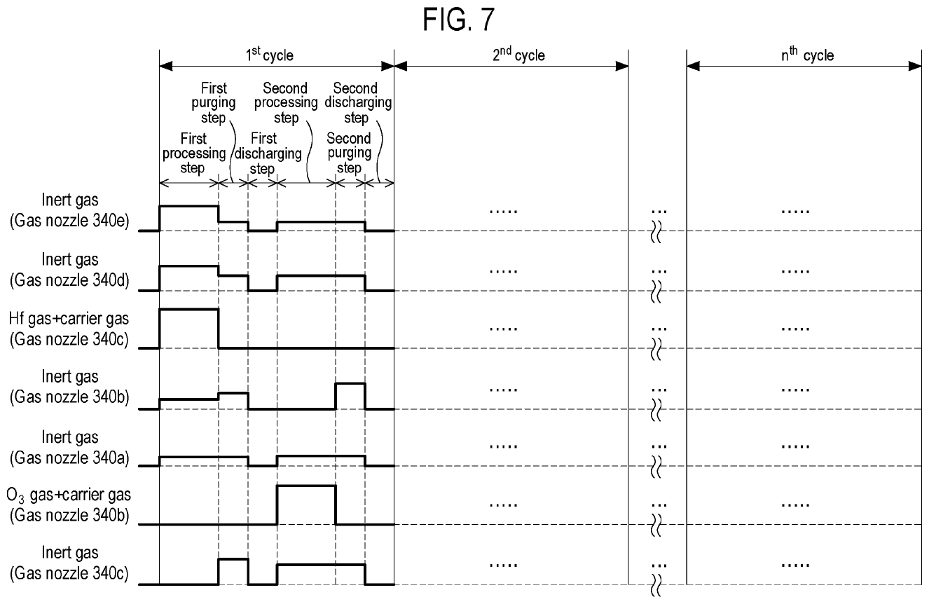

Next, an outline of the operation of the substrate processing apparatus according to some embodiments of the present disclosure will be described with a film-forming sequence shown in FIGS. 6 and 7 according to a control procedure performed by the controller 280. FIG. 6 shows an example of the film-forming sequence in a case of forming a film on a wafer 200 under a condition of strengthening convexity. FIG. 7 shows an example of the film-forming sequence in a case of forming a film on the wafer 200 under a condition of weakening the convexity. The boat 217 on which a predetermined number of wafers 200 are mounted is loaded into the reaction tube 203 in advance, and the reaction tube 203 is air-tightly closed by the seal cap 219.

When control by the controller 280 is started, the controller 280 operates the vacuum pump 246 and the APC valve 244 shown in FIG. 1 to exhaust an internal atmosphere of the reaction tube 203 via the exhaust port 230. Further, the controller 280 controls the rotation mechanism 267 to start the rotation of the boat 217 and the wafer 200. This rotation is continuously performed at least until the processing on the wafer 200 is completed.

In the film-forming sequence shown in FIGS. 6 and 7, a cycle including a first processing step, a first purging step, a first discharging step, a second processing step, a second purging step, and a second discharging step is performed a predetermined number of times to complete a film formation on the wafer 200. Then, when this film formation is completed, the boat 217 is unloaded from the interior of the reaction tube 203 according to a reverse procedure of the above-mentioned operation. Further, the wafer 200 is transferred from the boat 217 to a pod of a transfer shelf by a wafer transfer machine (not shown), and the pod is transferred from the transfer shelf to a pod stage by a pod transfer machine and is unloaded out of a housing by an external transfer mechanism.

### [Example of Film-Forming Sequence to Strengthen Convexity]

Hereinafter, an example of a film-forming sequence in a case of forming a film on the wafer 200 under a condition of strengthening the convexity will be described with reference to FIG. 6. In a state before the film-forming sequence is executed, the valves 330a to 330g are closed.

### First Processing Step

When the internal atmosphere of the reaction tube 203 is exhausted via the exhaust port 230 by the control of various components by the controller 280, the controller 280 opens the valves 330c and 330g and causes a Hf gas as a second precursor gas and a N₂ gas as a carrier gas to be injected from the injection holes 234c-1 and 234c-2 of the gas nozzle 340c. That is, the controller 280 causes the Hf gas and the N₂ gas to be ejected from the injection holes 234c-1 and 234c-2 of the gas nozzle 340c arranged in the second nozzle chamber 222b.

Further, the controller 280 opens the valves 330a, 330d, 330e, and 330f and causes a N₂ gas as an inert gas to be injected from the injection holes 234a, 234b, 234d, and 234e of the gas nozzles 340a, 340b, 340d, and 340e.

At this time, the controller 280 operates the vacuum pump 246 and the APC valve 244 so that a pressure obtained from the pressure sensor 245 becomes constant, to discharge the internal atmosphere of the reaction tube 203 via the exhaust port 230, thus setting the interior of the reaction tube 203 to a negative pressure. As a result, the Hf gas flows in parallel on the wafer 200, flows from the upper portion to the lower portion of the space S via the first exhaust port 236 and the second exhaust port 237, and then is exhausted via the exhaust pipe 231 via the exhaust port 230.

Here, the controller 280 controls the flow rate of the Hf gas supplied into the process chamber 201 by the MFCs 320c and 320g and the flow rate of the N₂ gas supplied into the process chamber 201 by the MFCs 320a, 320d, 320e, and 320f. Specifically, the controller 280 makes the flow rate of the N₂ gas supplied to the gas nozzle 340b close to the gas nozzle 340c equal to the flow rate of the N₂ gas supplied to the gas nozzle 340d close to the gas nozzle 340c, among the gas nozzles 340a, 340b, 340d, and 340e. Further, the controller 280 makes the flow rate of the N₂ gas supplied to the gas nozzle 340a far from the gas nozzle 340c equal to the flow rate of the N₂ gas supplied to the gas nozzle 340e far from the gas nozzle 340c, among the gas nozzles 340a, 340b, 340d, and 340e. Further, the controller 280 performs control to make a total flow rate of the N₂ gas supplied to the gas nozzles 340a and 340b installed at the right side of the gas nozzle 340c in the circumferential direction equal to a total flow rate of the N₂ gas supplied to the gas nozzles 340d and 340e installed at the left side of the gas nozzle 340c in the circumferential direction. That is, the controller 280 performs control such that a left-side flow rate and a right-side flow rate of the N₂ gas supplied to the gas nozzles 340a and 340b and the gas nozzles 340d and 340e installed respectively at both sides of the gas nozzle 340c become the same (equal to each other). That is, the controller 280 performs control such that the flow rates of the N₂ gases respectively supplied by the MFCs 320a, 320d, 320e, and 320f to the gas nozzles 340a, 340b, 340d, and 340e installed at both sides of the gas nozzle 340c become symmetrical, that is, the same on the left side and the right side, with respect to the gas nozzle 340c configured to supply the Hf gas. Although the flow rates of the N₂ gases supplied respectively to the gas nozzles 340a, 340b, 340d, and 340e are described, the description is not limited thereto, and the controller 280 may perform control so that the partial pressure or concentration distribution of the N₂ gases supplied respectively to the gas nozzles 340a, 340b, 340d, and 340e becomes symmetrical on the left side and the right side (the same on the left side and the right side) with respect to the gas nozzle 340c.

Further, the controller 280 makes the flow rate of the N₂ gas supplied to the gas nozzles 340b and 340d close to the gas nozzle 340c different from the flow rate of the N₂ gas supplied to the gas nozzles 340a and 340e far from the gas nozzle 340c, among the gas nozzles 340a, 340b, 340d, and 340e. Specifically, the controller 280 makes the flow rate of the N₂ gas supplied to the gas nozzles 340b and 340d close to the gas nozzle 340c higher than the flow rate of the N₂ gas supplied to the gas nozzles 340a and 340e far from the gas nozzle 340c. More specifically, the controller 280 may set a ratio of the flow rate of the N₂ gas supplied to the gas nozzles 340b and 340d close to the gas nozzle 340c and the flow rate of the N₂ gas supplied to the gas nozzles 340a and 340e far from the gas nozzle 340c to 4.5 or more within a range not exceeding the flow rate of the N₂ gas supplied to the gas nozzle 340c. As a result, the flow of the N₂ gas supplied from the gas nozzles 340b and 340d close to the gas nozzle 340c configured to supply the Hf gas may be assisted by the N₂ gas supplied from the gas nozzles 340a and 340e far from the gas nozzle 340c.

A process condition in this step is exemplified as follows.

N₂ gas supply flow rate of N₂ gas supplied from gas nozzle 340e: 1 slm

N₂ gas supply flow rate of N₂ gas supplied from gas nozzle 340d: 4.5 slm

Hf gas supply flow rate of Hf gas supplied from gas nozzle 340c: 0.12 slm

N₂ gas supply flow rate of N₂ gas supplied from gas nozzle 340c: 26.5 slm

N₂ gas supply flow rate of N₂ gas supplied from gas nozzle 340b: 4.5 slm

N₂ gas supply flow rate supplied from gas nozzle 340a: 1 slm

Processing pressure: 1 to 1,000 Pa, specifically 1 to 300 Pa, more specifically 100 to 250 Pa

Processing temperature: room temperature to 600 degrees C., specifically 90 to 550 degrees C., more specifically 450 to 550 degrees C., still more specifically 200 to 300 degrees C.

Further, the processing temperature may set to be lower than a temperature at which a precursor gas is decomposed.

Further, as described above, in the embodiments, the supply flow rate of the carrier gas (the supply flow rate of the N₂ gas supplied from the gas nozzle 340c) is made higher than the supply flow rate of the Hf gas. That is, the controller 280 performs control such that the flow rate of the Hf gas supplied to the gas nozzle 340c is lower than the flow rate of the N₂ gas supplied to the gas nozzle 340c. Further, the controller 280 performs control such that the flow rate of the N₂ gas supplied to the gas nozzle 340c is higher than the flow rate of the N₂ gas supplied to the gas nozzles 340a, 340b, 340d, and 340e. As a result, dilution of Hf gas is suppressed.

Further, the controller 280 may make the flow rate of the N₂ gas supplied to the gas nozzles 340b and 340d close to the gas nozzle 340c lower than the flow rate of the N₂ gas supplied to the gas nozzles 340a and 340e far from the gas nozzle 340c. In a case where the flow rate of the N₂ gas supplied to the gas nozzles 340b and 340d close to the gas nozzle 340c is made higher, the Hf gas as the second precursor gas may be lowered in concentration. By making the flow rate of the N₂ gas supplied to the gas nozzles 340b and 340d close to the gas nozzle 340c lower than the flow rate of the N₂ gas supplied to the gas nozzles 340a and 340e far from the gas nozzle 340c, a flow of the Hf gas may be assisted while suppressing the dilution of the Hf gas. Therefore, an effect of making the film thickness distribution of a hafnium oxide (HfO) film formed on the wafer 200 convex may be enhanced.

### First Purging Step

When the first processing step is completed with lapse of a predetermined time, the controller 280 closes the valve 330c to stop the supply of the Hf gas from the gas nozzle 340c. Further, the controller 280 makes the supply flow rate of the N₂ gas by the MFCs 320f and 320g higher than that in the first process step and supplies the N₂ gas as a purge gas into the process chamber 201 from the gas nozzles 340a to 340e to purge out a gas staying inside the reaction tube 203 via the exhaust port 230.

A process condition in this step is exemplified as follows.

N₂ gas supply flow rate supplied from gas nozzle 340e: 1 slm

N₂ gas supply flow rate supplied from gas nozzle 340d: 4.5 slm

N₂ gas supply flow rate supplied from gas nozzle 340c: 10 slm

N₂ gas supply flow rate supplied from gas nozzle 340b: 5 slm

N₂ gas supply flow rate supplied from gas nozzle 340a: 1 slm

### First Discharging Step

When the first purging step is completed with lapse of a predetermined time, the controller 280 closes the valves 330a to 330g to stop the supply of the N₂ gas from the gas nozzles 340a to 340e.

Further, the controller 280 controls the vacuum pump 246 and the APC valve 244 to increase a degree of internal negative pressure of the reaction tube 203 to exhaust the internal atmosphere of the reaction tube 203 via the exhaust port 230.

### Second Processing Step

When the first discharging step is completed with lapse of a predetermined time, the controller 280 opens the valves 330b and 330f and causes an O₃ gas as the first precursor gas and a N₂ gas as the carrier gas to be injected from the injection hole 234b of the gas nozzle 340b. That is, the controller 280 causes the O₃ gas and the N₂ gas to be ejected from the injection hole 234b of the gas nozzle 340b arranged in the first nozzle chamber 222a.

Further, the controller 280 opens the valves 330a, 330d, 330e, and 330g and causes a N₂ gas as an inert gas to be injected from the injection holes 234a, 234c-1, 234c-2, 234d, and 234e of the gas nozzles 340a, 340c, 340d, and 340e.

At this time, the controller 280 operates the vacuum pump 246 and the APC valve 244 so that a pressure obtained from the pressure sensor 245 becomes constant, to discharge the internal atmosphere of the reaction tube 203 via the exhaust port 230 to set the interior of the reaction tube 203 to a negative pressure.

As a result, the first precursor gas flows in parallel on the wafer 200, flows from the upper portion to the lower portion of the space S via the first exhaust port 236 and the second exhaust port 237, and then is exhausted through the exhaust pipe 231 via the exhaust port 230.

A process condition in this step is exemplified as follows

N₂ gas supply flow rate supplied from gas nozzle 340e: 1 slm

N₂ gas supply flow rate supplied from gas nozzle 340d: 4.5 slm

N₂ gas supply flow rate supplied from gas nozzle 340c: 4.5 slm

O₃ gas supply flow rate supplied from gas nozzle 340b: 22 slm

N₂ gas supply flow rate supplied from gas nozzle 340b: 1.5 slm

N₂ gas supply flow rate supplied from gas nozzle 340a: 1 slm

### Second Purging Step

When the second processing step is completed with lapse of a predetermined time, the controller 280 closes the valve 330b to stop the supply of the O₃ gas from the gas nozzle 340b. Further, the controller 280 increases the supply flow rate of a N₂ gas by the MFC 320f and supplies a N₂ gas as a purge gas into the process chamber 201 from the gas nozzles 340a to 340e to purge out a gas staying inside the reaction tube 203 via the exhaust port 230.

A process condition in this step is exemplified as follows.

N₂ gas supply flow rate supplied from gas nozzle 340e: 1 slm

N₂ gas supply flow rate supplied from gas nozzle 340d: 4.5 slm

N₂ gas supply flow rate supplied from gas nozzle 340c: 4.5 slm

N₂ gas supply flow rate supplied from gas nozzle 340b: 10 slm

N₂ gas supply flow rate supplied from gas nozzle 340a: 1 slm

### Second Discharging Step

When the second purging step is completed with lapse of a predetermined time, the controller 280 closes the valves 330a to 330g to stop the supply of the N₂ gas from the gas nozzles 340a to 340e.

Further, the controller 280 controls the vacuum pump 246 and the APC valve 244 to increase the degree of internal negative pressure of the reaction tube 203 to exhaust the internal atmosphere of the reaction tube 203 via the exhaust port 230.

As described above, by performing a cycle a predetermined number of times, the cycle including the first processing step, the first purging step, the first discharging step, the second processing step, the second purging step, and the second discharging step, the HfO film is formed on the wafer 200 to strengthen the convexity, and the process is completed.

### [Example of Film-Forming Sequence to Weaken Convexity]

Hereinafter, an example of the film-forming sequence in a case where a film is formed on a wafer 200 under a condition where a convexity is weakened will be described with reference to FIG. 7. This sequence example is different from the above-described film-forming sequence in the first processing step, and therefore, the different first processing step will be described.

### First Processing Step

When the internal atmosphere of the reaction tube 203 is exhausted via the exhaust port 230 by control of various components by the controller 280, the controller 280 opens the valves 330c and 330g and causes a Hf gas as a second precursor gas and a N₂ gas as a carrier gas to be injected from the injection holes 234c-1 and 234c-2 of the gas nozzle 340c. That is, the controller 280 causes the Hf gas and the N₂ gas to be ejected from the injection holes 234c-1 and234c-2 of the gas nozzle 340c arranged in the second nozzle chamber 222b.

Further, the controller 280 opens the valves 330a, 330d, 330e, and 330f and causes a N₂ gas as an inert gas to be injected from the injection holes 234a, 234b, 234d, and 234e of the gas nozzles 340a, 340b, 340d, and 340e.

At this time, the controller 280 operates the vacuum pump 246 and the APC valve 244 such that a pressure obtained from the pressure sensor 245 becomes constant, to discharge the internal atmosphere of the reaction tube 203 via the exhaust port 230, thus setting the interior of the reaction tube 203 to a negative pressure. As a result, the Hf gas flows in parallel on the wafer 200, flows from the upper portion to the lower portion of the space S via the first exhaust port 236 and the second exhaust port 237, and then is exhausted through the exhaust pipe 231 via the exhaust port 230.

Here, the controller 280 controls the flow rate of the Hf gas supplied into the process chamber 201 by the MFCs 320c and 320g and the flow rate of the N₂ gas supplied into the process chamber 201 by the MFCs 320a, 320d, 320e, and 320f. Specifically, the controller 280 makes the flow rate of the N₂ gas supplied to the gas nozzle 340d equal to the flow rate of the N₂ supplied to the gas nozzle 340e, among the gas nozzles 340a, 340b, 340d, and 340e. Further, the controller 280 makes the flow rate of the N₂ gas supplied to the gas nozzle 340a equal to the flow rate of the N₂ gas supplied to the gas nozzle 340b, among the gas nozzles 340a, 340b, 340d, and 340e. That is, the controller 280 makes the flow rate of the N₂ gas supplied to the gas nozzles 340a and 340b arranged on the right side of the gas nozzle 340c in the circumferential direction different from the flow rate of the N₂ gas supplied to the gas nozzles 340d and 340e arranged on the left side of the gas nozzle 340c in the circumferential direction. For example, the controller 280 makes the flow rate of the N₂ gas supplied to the gas nozzles 340b and 340a on the right side of the gas nozzle 340c in the circumferential direction lower than the flow rate of the N₂ gas supplied to the gas nozzles 340d and 340e on the left side of the gas nozzle 340c in the circumferential direction. That is, the controller 280 performs control such that the flow rates of the N₂ gases supplied to the gas nozzles 340a, 340b, 340d, and 340e become asymmetrical, that is, different on the left side and the right side, with respect to the gas nozzle 340c. The flow rates of the N₂ gases supplied respectively to the gas nozzles 340a, 340b, 340d, and 340e are described above but the description is not limited thereto, and the controller 280 may perform control such that the partial pressure or concentration distribution of the N₂ gases supplied respectively to the gas nozzles 340a, 340b, 340d, and 340e becomes asymmetrical (different on the left side and the right side) with respect to the gas nozzle 340c.

A process condition in this step is exemplified as follows.

N₂ gas supply flow rate supplied from gas nozzle 340e: 12 to 19 slm

N₂ gas supply flow rate supplied from gas nozzle 340d: 12 to 19 slm

Hf gas supply flow rate supplied from gas nozzle 340c: 0.12 slm

N₂ gas supply flow rate supplied from gas nozzle 340c: 14 to 26.5 slm

N₂ gas supply flow rate supplied from gas nozzle 340b: 1 slm

N₂ gas supply flow rate supplied from gas nozzle 340a: 1 slm

Processing pressure: 1 to 1,000 Pa, specifically 1 to 300 Pa, more specifically 100 to 250 Pa Processing temperature: room temperature to 600 degrees C., specifically 90 to 550 degrees C., more specifically 450 to 550 degrees C., still more specifically 200 to 300 degrees C.

Further, the processing temperature may be set to be lower than a temperature at which a precursor gas is decomposed.

Further, as described above, in the embodiments, the supply flow rate of the carrier gas (the supply flow rate of the N₂ gas supplied from the gas nozzle 340c) is made higher than the supply flow rate of the Hf gas. That is, the controller 280 performs control such that the flow rate of the Hf gas supplied to the gas nozzle 340c is lower than the flow rate of the N₂ gas supplied to the gas nozzle 340c. Further, the controller 280 performs control such that the flow rate of the N₂ gas supplied to the gas nozzle 340c is lower than the total flow rate of the N₂ gases supplied to the gas nozzles 340d and 340e. Further, the controller 280 performs control such that the flow rate of the N₂ gas supplied to the gas nozzle 340c is higher than the total flow rate of the N₂ gases supplied to the gas nozzles 340a and 340b. Further, the controller 280 performs a control such that the total flow rate of the N₂ gas supplied to the gas nozzles 340a and 340b is lower than the total flow rate of the N₂ gases supplied to the gas nozzles 340d and 340e. Further, the flow rates of the N₂ gases supplied to the gas nozzles 340a and 340b are flow rates each capable of suppressing backflows in the gas nozzles.

Then, by performing a cycle a predetermined number of times, the cycle including the first processing step, the aforementioned first purging step, a first discharging step, a second processing step, a second purging step, and a second discharging step, a HfO film is formed on the wafer 200 to weaken the convexity, and the process is completed.

### (Summary)

As described above, in the substrate processing apparatus 10, the gas nozzles 340a and 340b and the gas nozzles 340d and 340e configured to supply the N₂ gas as the inert gas are arranged on both sides of the gas nozzle 340c through which the Hf gas as the second precursor gas flows. Further, the MFCs 320a, 320d, 320e, and 320f are installed and controlled independently between the gas nozzles 340a, 340b, 340d, and 340e and the inert gas supply sources 360a, 360d, 360e, and 360f configured to supply the N₂ gas to these gas nozzles, respectively. Further, the MFCs 320c and 320g are installed between the gas nozzle 340c and the second precursor gas supply source 360c configured to supply the Hf gas and between the gas nozzle 340c and the inert gas supply source 360g configured to supply the N₂ gas, respectively.

Therefore, it is possible to control the supply amount of N₂ gas injected from the injection hole 234a of the gas nozzle 340a, the supply amount of N₂ gas injected from the injection hole 234b of the gas nozzle 340b, the supply amount of N₂ gas injected from the injection hole 234d of the gas nozzle 340d, and the supply amount of N₂ gas injected from the injection hole 234e of the gas nozzle 340e, respectively. Further, it is possible to control the supply amount of Hf gas and the supply amount of N₂ gas injected from the injection holes 234c-1 and 234c-2 of the gas nozzle 340c, respectively.

Further, the gas nozzle 340c configured to supply the Hf gas as the second precursor gas is sandwiched, in the circumferential direction of the process chamber 201, between the gas nozzles 340a and 340b configured to supply the N₂ gas as the inert gas and the gas nozzles 340d and 340e configured to supply the N₂ gas as the inert gas. Then, the controller 280 can control the flow rates of the inert gases supplied from the gas nozzles 340a, 340b, 340d, and 340e on both sides of the gas nozzle 340c when the Hf gas is supplied, thereby controlling a film thickness distribution of a film formed on the wafer 200.

Further, the controller 280 controls the MFCs 320c and 320g to make the supply amount of N₂ gas injected from the injection holes 234c-1 and 234c-2 more than the supply amount of Hf gas injected from the injection holes 234c-1 and 234c-2, respectively. In this way, by flowing the Hf gas and the N₂ gas of the larger supply amount than the Hf gas from the second nozzle chamber 222b, the N₂ gas prevents diffusion of the Hf gas and the Hf gas reaches the center of the wafer 200. Therefore, it is possible to suppress variations in the film thickness of the film formed on the wafer 200 as compared with a case where the supply amount of N₂ gas is smaller than the supply amount of Hf gas.

### <Modifications>

Some modifications will be described below. In the modifications, portions different from those in the some embodiments described above will be mainly described.

### <First Modification>

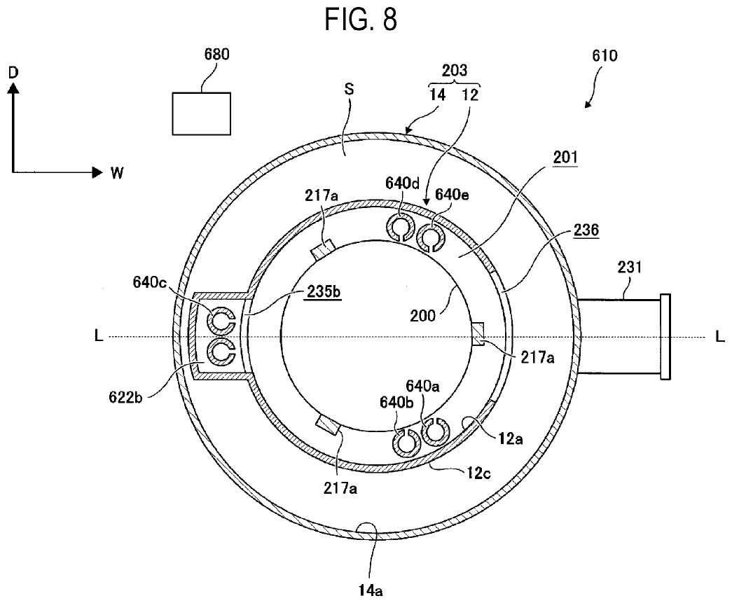

An example of a substrate processing apparatus 610 according to the modification will be described with reference to FIG. 8. The substrate processing apparatus 610 includes a nozzle chamber 622b corresponding to the second nozzle chamber 222b of the above-described embodiments, and does not include the first nozzle chamber 222a and the third nozzle chamber 222c of the above-described embodiments. The nozzle chamber 622b is provided with a gas nozzle 640c corresponding to the gas nozzle 340c of the above-described embodiments. Further, a gas nozzle 640a corresponding to the gas nozzle 340a of the above-described embodiments and a gas nozzle 640b corresponding to the gas nozzle 340b are installed, in proximity to the right side of the gas nozzle 640c in the circumferential direction, in a space between the inner peripheral surface 12a in the process chamber 201 and the wafer 200. Further, a gas nozzle 640d corresponding to the gas nozzle 340d of the above-described embodiments and a gas nozzle 640e corresponding to the gas nozzle 340e are installed, in proximity to the left side of the gas nozzle 640c in the circumferential direction, in the space between the inner peripheral surface 12a in the process chamber 201 and the wafer 200.

That is, as shown in FIG. 8, the gas nozzles 640a and 640b and the gas nozzles 640e and 640d configured to supply the N₂ gas are installed symmetrically with respect to the gas nozzle 640c configured to supply the Hf gas. That is, two or more gas nozzles 640a and 640b and two or more gas nozzles 640e and 640d as inert gas nozzles are respectively installed on both sides of a straight line L passing through the gas nozzle 640c as a process gas nozzle and the first exhaust port 236 in a plane view. Further, in this modification, the gas nozzles 640a and 640b and the gas nozzles 640e and 640d as the inert gas nozzles are arranged in line symmetry with the straight line L as the axis of symmetry. The gas nozzles 640a and 640b and the gas nozzles 640e and 640d as the inert gas nozzles may not be arranged in line symmetry.

Also in the substrate processing apparatus 610, it is possible to control a film thickness distribution of a HfO film formed on the wafer 200 by using the above-described film-forming sequences shown in FIGS. 6 and 7.

### <Second Modification>

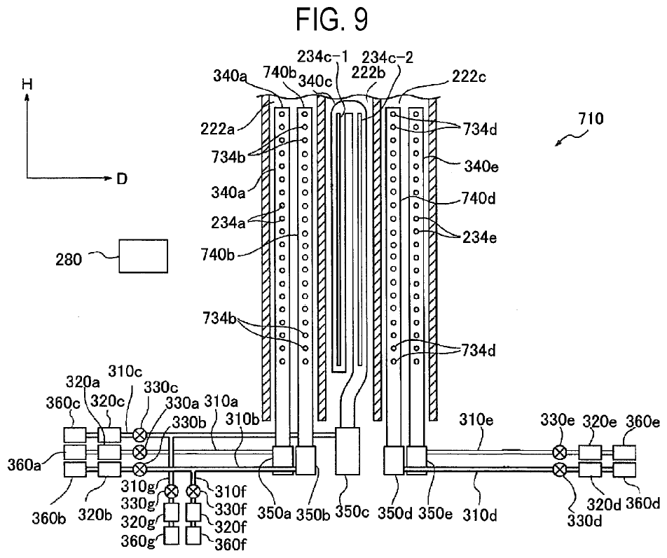

Next, an example of a substrate processing apparatus 710 according to another modification will be described with reference to FIG. 9.

As shown in FIG. 9, the substrate processing apparatus 710 includes a gas nozzle 740b corresponding to the gas nozzle 340b of the above-described embodiments and a gas nozzle 740d corresponding to the gas nozzle 340d of the above-described embodiments.

Similar to the gas nozzles 340a and 340e, the gas nozzles 740b and 740d are provided with a plurality of pinhole-shaped injection holes 734b and 734d arranged in the vertical direction. A range in which the injection holes 734b and 734d are formed in the vertical direction covers the range in which the wafers 200 are arranged in the vertical direction.

That is, as shown in FIG. 9, the gas nozzles 340a and 740b and the gas nozzles 740d and 340e configured to supply the N₂ gas are installed symmetrically with respect to the gas nozzle 340c configured to supply the Hf gas.

Also in the substrate processing apparatus 710, it is possible to control a film thickness distribution of a HfO film formed on the wafer 200 by using the above-described film-forming sequences shown in FIGS. 6 and 7.

### <Third Modification>

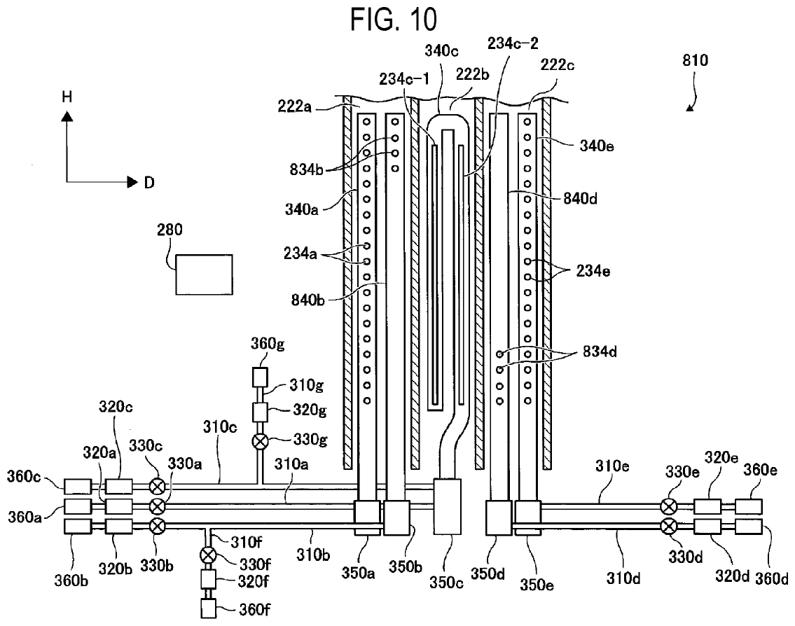

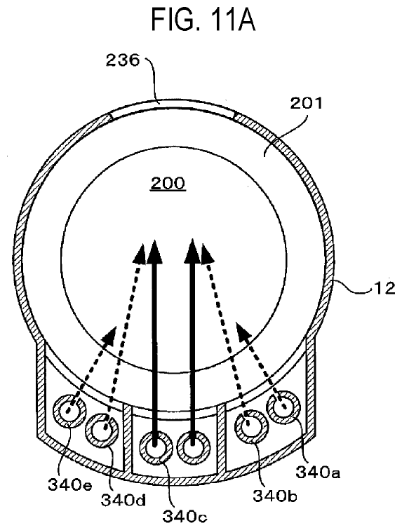

Next, an example of a substrate processing apparatus 810 according to another modification will be described with reference to FIG. 10.

As shown in FIG. 10, the substrate processing apparatus 810 includes a gas nozzle 840b corresponding to the gas nozzle 340b of the above-described embodiments and a gas nozzle 840d corresponding to the gas nozzle 340d of the above-described embodiments.

In the gas nozzle 840b, a plurality of pinhole-shaped injection holes 834b arranged in a vertical direction are formed in an upper portion, but not in a lower portion, of the gas nozzle 840b in the vertical direction. Further, in the gas nozzle 840d, a plurality of pinhole-shaped injection holes 834d arranged in the vertical direction are formed in a lower portion, but not in an upper portion, of the gas nozzle 840d in the vertical direction. The injection holes 834b formed in the upper portion of the gas nozzle 840b cover, in the vertical direction, a range in which the uppermost wafer 200 is arranged. Further, the injection holes 834d formed in the lower portion of the gas nozzle 840d covers a range, in the vertical direction, in which the lowermost wafer 200 is arranged. Further, the injection holes 834b and 834d are formed to face the supply slits 235a and 235c, respectively.

That is, as shown in FIG. 10, the gas nozzles 340a and 840b and the gas nozzles 840d and 340e configured to supply the N₂ gas are installed symmetrically on the left side and the right side with respect to the gas nozzle 340c configured to supply the Hf gas.

Also in the substrate processing apparatus 810, it is possible to control a film thickness distribution of a HfO film formed on the wafer 200 by using the above-described film-forming sequences shown in FIGS. 6 and 7. Further, according to the substrate processing apparatus 810, it is possible to independently control film thicknesses of films formed on the wafers 200 in an upper region and a lower region of the wafers 200 supported by the boat 217.

### <Other Embodiments>

Some embodiments of the present disclosure are specifically described above. However, the present disclosure is not limited to the above-described embodiments, and various changes may be made without departing from the gist thereof.

Further, in the above-described embodiments, the configuration in which two gas nozzles configured to supply the inert gas are installed on each of both sides of the gas nozzle 340c is described, but the present disclosure is not limited thereto, and even when one gas nozzle configured to supply the inert gas is installed, the same effect may obtained. By installing two or more gas nozzles configured to supply the inert gas on each of both sides of the gas nozzle 340c, it is possible to improve a controllability. Further, since there is an upper limit to the flow rate of the inert gas that may be supplied to one gas nozzle, a plurality of gas nozzles may be installed to secure a high flow rate.

Further, in the above-described embodiments, the configuration in which the U-typed (U-shaped) gas nozzle is used as the gas nozzle 340c is described, but the present disclosure is not limited thereto and may apply to even a case where an I-typed gas nozzle is used, whereby the same effect is obtained. Further, the configuration in which the slit-shaped injection holes 234c-1 and 234c-2 are formed in the gas nozzle 340c is described above, but the present disclosure is not limited thereto and may apply to even a case where a plurality of pinhole-shaped injection holes are installed in the vertical direction, whereby the same effect is obtained.

Further, in the above-described embodiments, the process of repeatedly performing the first processing step, the first purging step, the first discharging step, the second processing step, the second purging step, and the second discharging step are described, but the present disclosure is not limited thereto and may apply to even a case where a Hf gas supply step as the first processing step, the purging step, and the discharging step are repeatedly performed, an O₃ gas supply step as the second processing step, the purging step, and the discharging step are repeatedly performed, and then the purging step and the discharging step are repeatedly performed, whereby the same effect is obtained.

Further, in the above-described embodiments, the case where the HfO film is formed on the wafer 200 is described, but the present disclosure is not limited thereto and may be applied to even a case where a precursor gas is supplied when forming other films such as an aluminum oxide (AlO) film, a zirconium oxide (ZrO) film, a silicon oxide (SiO) film, a silicon nitride (SiN) film, a titanium nitride (TiN) film, a tungsten (W) film, a molybdenum (Mo) film, and a molybdenum nitride (MoN) film. Further, the present disclosure may be applied to even a case of forming a laminated film containing at least two or more selected from the group of these materials. Further, the present disclosure may be applied to even a case of forming a composite film containing at least two or more selected from the group of these materials. When forming these films, the present disclosure may be similarly applied and may obtain the same effects by appropriately regulating the flow rate, processing pressure, processing temperature, and the like of the gas supplied from each gas nozzle. That is, in a case of using, as the precursor gas, a trimethylaluminum (TMA) gas, a tetrakisethylmethylaminozirconium (TEMAZ) gas, a hexachlorodisilane (HCDS) gas, a titanium tetrachloride (TiCl₄) gas, a tetrakisdimethylaminotitanium (TDMAT) gas, a tungsten hexafluoride (WF₆) gas, a molybdenum pentachloride (MoCl₅) gas, a molybdenum oxychloride (MoOCl₄, MoO₂Cl₂) gas, and the like, in addition to the Hf gas, the present disclosure may be similarly applied and may obtain the same effect by appropriately regulating the flow rate, processing pressure, processing temperature, and the like of the gas supplied from each gas nozzle.

Further, in the above-described embodiments, the substrate processing apparatus including the vertical process furnace is described but the present disclosure is not limited thereto, and the technique of the present disclosure may be applied to even a substrate processing apparatus (also referred to as a single-wafer apparatus) configured to process one substrate (wafer 200) in one process chamber. For example, the present disclosure may be applied to a substrate processing apparatus of a configuration in which a process gas is supplied from a side of a substrate.

Hereinafter, Examples will be described.

### EXAMPLES

By using the above-described substrate processing apparatus 10 and the film-forming sequence (the condition under which the convex distribution is strengthened) in FIG. 6 to change a flow rate ratio of a N₂ gas supplied from each gas nozzle in the first processing step, a film thickness of a HfO film formed on a wafer of a diameter of 300 mm was measured.

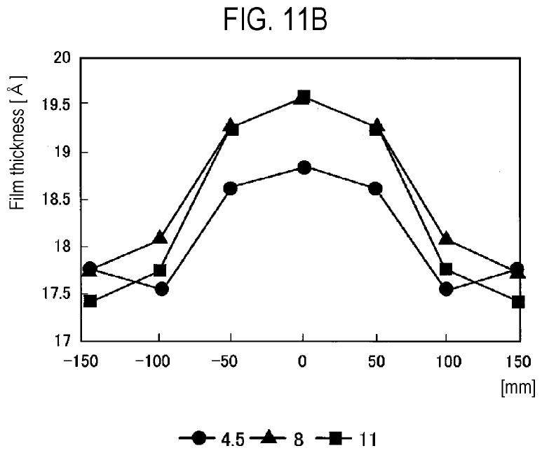

FIG. 11A is a diagram schematically showing a gas flow in the process chamber in the first processing step of the film-forming sequence of FIG. 6. FIG. 11B is a diagram showing a film thickness distribution of the film formed on the wafer by the film-forming sequence of FIG. 6.

Specifically, a flow rate of a Hf gas supplied to the nozzle 340c was set to 0.12 slm, a flow rate of a N₂ gas supplied to the nozzle 340c was set to 26.5 slm, a flow rate of a N₂ gas supplied to the nozzles 340a and 340e was set to 1 slm, and a flow rate of a N₂ gas supplied to the nozzles 340b and 340d was changed to 4.5 to 11 slm, and the film thickness of the HfO film formed on the wafer was measured.

That is, the film thickness of the HfO film formed on the wafer when the N₂ gas is supplied with a flow rate symmetrical on the left side and the right side with respect to the Hf gas was compared by changing the flow rate ratio of the N₂ gas supplied from each gas nozzle. With the flow rate of the N₂ gas supplied to the nozzle 340d/the flow rate of the N₂ gas supplied to the nozzle 340e=the flow rate of the N₂ gas supplied to the nozzle 340b/the flow rate of the N₂ gas supplied to the nozzle 340a, the film thickness of the HfO film formed on the wafer was compared by changing the flow rate ratio to 4.5, 8, and 11.

As shown in FIG. 11B, the HfO film was formed in a convex shape on the wafer in the flow rate ratios of 4.5, 8, and 11. Further, the film with stronger convexity was formed on the wafer in the case of the flow rate ratios of 8 and 11 than in the case of the flow rate ratio of 4.5. Further, the film thickness at the end portion of the wafer was formed thinner in the case of the flow rate ratio of 11 than in the case of the flow rate ratios of 4.5 and 8. That is, by making the flow rate of the N₂ gas supplied from a gas nozzle close to a supply side of the Hf gas higher than the flow rate of the N₂ gas supplied from a gas nozzle far from the supply side of the Hf gas, with the flow rates of the N₂ gases supplied from both sides of the Hf gas symmetrical on the left side and the right side of the HF gas, the HfO film with strong convexity was formed on the wafer. That is, by increasing the flow rate of the N₂ gas on both sides of the Hf gas, the flow rate of the Hf gas to the central portion of the wafer may be increased to strengthen the convex distribution. Therefore, by setting a ratio of the flow rate of the N₂ gas supplied to the gas nozzles 340b and 340d close to the gas nozzle 340c and the flow rate of the N₂ gas supplied to the gas nozzles 340a and 340e far from the gas nozzle 340c to 4.5 or more within a range not exceeding the flow rate of the N₂ gas supplied to the gas nozzle 340c, the HfO film can be formed in the convex shape on the wafer.

Next, by using the above-described substrate processing apparatus 10 and the film-forming sequence (the condition under which the convex distribution is weakened) in FIG. 7 to change the flow rate ratio of a N₂ gas supplied from each gas nozzle in the first processing step, a film thickness of a HfO film formed on a wafer of a diameter of 300 mm was measured.

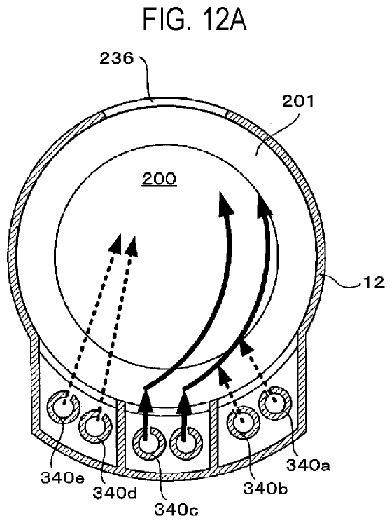

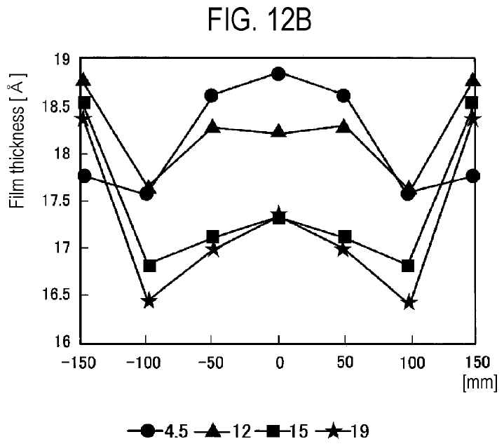

FIG. 12A is a diagram schematically showing a gas flow in the process chamber in the first processing step of the film-forming sequence of FIG. 7. FIG. 12B is a diagram showing a film thickness distribution of a film formed on a wafer by the film-forming sequence of FIG. 7.

Specifically, the flow rate of the Hf gas supplied to the nozzle 340c was set to 0.12 slm, the flow rate of the N₂ gas supplied to the nozzle 340c was set to 26.5 slm, the flow rate of the N₂ gas supplied to the nozzles 340a and 340b was set to 1 slm, and the flow rate of the N₂ gas supplied to the nozzles 340d and 340e was changed to 12 to 19 slm, and the film thickness of the HfO film formed on the wafer was measured.

That is, the film thickness of the HfO film formed on the wafer when the N₂ gas is supplied with a flow rate asymmetrical on the left side and the right side with respect to the Hf gas was compared by changing the flow rate ratio of the N₂ gas supplied from each gas nozzle. Specifically, with the flow rate of the N₂ gas supplied to the nozzle 340d/the flow rate of the N₂ gas supplied to the nozzle 340b=the flow rate of the N₂ gas supplied to the nozzle 340e/the flow rate of the N₂ gas supplied to the nozzle 340a, the film thickness of the HfO film formed on the wafer was compared by changing the flow rate ratio to 4.5, 12, 15, and 19.

As shown in FIG. 12B, the HfO film with weaker convexity was formed on the wafer in the case of the flow rate ratios of 12, 15, and 19 than in the case of the flow rate ratio of 4.5. Further, the HfO film with weaker convexity (in a concave shape) was formed in the central portion of the wafer in the case of the flow rate ratios of 15 and 19 than in the case of the flow rate ratio of 12. That is, as a ratio between the flow rate of the N₂ gas supplied from one side of the Hf gas and the flow rate of the N₂ gas supplied from the other side of the HF gas becomes higher, the HfO film with weaker convexity (in a concave shape) was formed on the wafer. That is, by making the flow rate of the N₂ gas on one side of the Hf gas higher than the flow rate of the N₂ gas on the other side of the Hf gas, it was possible to increase the flow rate of the Hf gas to the end portion of the wafer, thereby weakening the convex distribution.

According to the present disclosure in some embodiments, it is possible to control a film thickness distribution of a film formed on a substrate.

While certain embodiments are described above, these embodiments are presented by way of example, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus comprising:
a process gas nozzle configured to supply a process gas into a process chamber;
two or more inert gas nozzles installed at each of both sides of the process gas nozzle in a circumferential direction of the process chamber and configured to supply an inert gas into the process chamber;
a process gas supplier configured to supply the process gas to the process gas nozzle;
an inert gas supplier configured to supply the inert gas to each of the inert gas nozzles; and
a controller configured to be capable of controlling a flow rate of the process gas supplied from the process gas supplier to the process gas nozzle and a flow rate of the inert gas supplied from the inert gas supplier to each of the inert gas nozzles, respectively.

2. The substrate processing apparatus of claim 1, wherein the controller is configured to be capable of controlling the flow rate of the inert gas supplied to each of the inert gas nozzles to be symmetrical or asymmetrical with respect to the process gas nozzle.

3. The substrate processing apparatus of claim 2, wherein the controller is configured to be capable of controlling the flow rates of the inert gases supplied to the inert gas nozzles installed at both sides of the process gas nozzle to be equal to each other.

4. The substrate processing apparatus of claim 1, wherein the controller is configured to be capable of making the flow rate of the inert gas supplied to an inert gas nozzle close to the process gas nozzle different from the flow rate of the inert gas supplied to an inert gas nozzle far from the process gas nozzle, among the inert gas nozzles.

5. The substrate processing apparatus of claim 4, wherein the controller is configured to be capable of making the flow rate of the inert gas supplied to the inert gas nozzle close to the process gas nozzle higher than the flow rate of the inert gas supplied to the inert gas nozzle far from the process gas nozzle.

6. The substrate processing apparatus of claim 4, wherein the controller is configured to be capable of making the flow rate of the inert gas supplied to the inert gas nozzle close to the process gas nozzle lower than the flow rate of the inert gas supplied to the inert gas nozzle far from the process gas nozzle.

7. The substrate processing apparatus of claim 4, wherein the controller is configured to be capable of setting a ratio of the flow rate of the inert gas supplied to the inert gas nozzle close to the process gas nozzle to the flow rate of the inert gas supplied to the inert gas nozzle far from the process gas nozzle to 4.5 or more within a range not exceeding a flow rate of a N₂ gas supplied to the process gas nozzle.

8. The substrate processing apparatus of claim 1, wherein the process gas nozzle and the inert gas nozzles are arranged in respective partitioned spaces.

9. The substrate processing apparatus of claim 1, wherein the process gas and the inert gas are supplied to the process gas nozzle.

10. The substrate processing apparatus of claim 9, wherein the controller is configured to be capable of controlling the flow rate of the process gas supplied to the process gas nozzle to be lower than a flow rate of the inert gas supplied to the process gas nozzle.

11. The substrate processing apparatus of claim 10, wherein the controller is configured to be capable of controlling the flow rate of the inert gas supplied to the process gas nozzle to be higher than the flow rate of the inert gas supplied to each of the inert gas nozzles.

12. The substrate processing apparatus of claim 1, further comprising: an exhaust port facing the process gas nozzle,
wherein each of the inert gas nozzles is installed at a side facing the exhaust port.

13. A non-transitory computer-readable recording medium storing a program that causes, by a computer, a substrate processing apparatus to perform a process in a process chamber of the substrate processing apparatus, the process comprising:
supplying a process gas, which is supplied from a process gas supplier, from a process gas nozzle into the process chamber;
supplying an inert gas, which is supplied from an inert gas supplier, from two or more inert gas nozzles installed at each of both sides of the process gas nozzle in a circumferential direction of the process chamber into the process chamber; and
controlling a flow rate of the process gas supplied from the process gas supplier to the process gas nozzle and a flow rate of the inert gas supplied from the inert gas supplier to each of the inert gas nozzles, respectively.

14. A method of processing a substrate, comprising:
supplying a process gas, which is supplied from a process gas supplier, from a process gas nozzle into a process chamber;
supplying an inert gas, which is supplied from an inert gas supplier, from two or more inert gas nozzles installed at each of both sides of the process gas nozzle in a circumferential direction of the process chamber into the process chamber; and
controlling a flow rate of the process gas supplied from the process gas supplier to the process gas nozzle and a flow rate of the inert gas supplied from the inert gas supplier to each of the inert gas nozzles, respectively.

15. A method of manufacturing a semiconductor device comprising the method of claim 14.
